(19) United States
(12) Patent Application Publication
(10) Pub. No.: US 2026/0177644 A1
(43) Pub. Date: Jun. 25, 2026

(54) MANUFACTURING SYSTEM AND MANUFACTURING METHOD OF FERROMAGNETIC SENSING MATERIAL

(71) Applicant: Industrial Technology Research Institute, Hsinchu (TW)

(72) Inventors: Liang-Juan Chang, Keelung City (TW); Cheng-Hsuan Lin, Hsinchu City (TW); Chien-Yu Lin, Kaohsiung City (TW); Yung-Jen Cheng, Hsinchu City (TW)

(73) Assignee: Industrial Technology Research Institute, Hsinchu (TW)

(21) Appl. No.: 18/991,695

(22) Filed: Dec. 23, 2024

(51) Int. Cl. G01R 33/00; G01R 33/09; H10N 50/01; H10N 50/10

(52) U.S. Cl. CPC G01R 33/0052; G01R 33/0094; G01R 33/098; H10N 50/01; H10N 50/10

(57) ABSTRACT

A manufacturing system of a ferromagnetic sensing material is used to process a raw material into the ferromagnetic sensing material. The manufacturing system of the ferromagnetic sensing material includes a rotating device, a working cavity, a carrying element, an array magnet module, a spin wave excitation device, a baffle module, a measuring device, and a control unit. The rotating device includes a rotating shaft. The carrying element is disposed in an internal space of the working cavity to carry the raw material. The array magnet module is used to provide a fixed magnetic field. The spin wave excitation device is used to provide a high-frequency magnetic field spin wave. The baffle module is used to change an electromagnetic wave distribution in the working cavity. The measuring device is used to measure the ferromagnetic sensing material. The control unit obtains a magnetization result of the ferromagnetic sensing material according to a reflected beam. The rotating device drives the carrying element and the array magnet module to rotate.

### TECHNICAL FIELD

The disclosure relates to a manufacturing system and a manufacturing method, and more particularly, to a manufacturing system and a manufacturing method of a ferromagnetic sensing material.

### BACKGROUND

A tunneling magnetoresistive magnetic sensor is one of important components in a battery management system of an electric vehicle and a three-dimensional navigation magnetic sensor chip of a drone. However, in a current high-temperature furnace annealing method, since a process temperature reaches 300 degrees Celsius, and it takes about 8 hours for heating and cooling, impurities in a magnetic layer are easy to diffuse into a tunneling layer or an antiferromagnetic layer, generating a smaller magnetic anisotropy field, resulting in reduced resolution and poor thermal stability of magnetic sensing, and it is time-consuming and detrimental to production efficiency. In addition, a multi-wave source microwave annealing method may be used to enhance perpendicular anisotropy of the magnetic layer, but without an external magnetic field, it may not control a direction of in-plane anisotropy of the magnetic layer, and a stage has no pattern design, making it impossible to define different spatial distributions of magnetic anisotropy on the same wafer. Therefore, a current manufacturing method faces challenges related to sensing accuracy and thermal stability. In addition, how to improve process efficiency of manufacturing a tunneling magnetoresistive sensor and significantly reduce production costs is also one of development goals in the art.

### SUMMARY

The disclosure provides a manufacturing system and a manufacturing method of a ferromagnetic sensing material, which may manufacture the ferromagnetic sensing material with characteristics of high sensing sensitivity, high tunneling magnetoresistance, and high thermal stability.

The disclosure provides a manufacturing system of a ferromagnetic sensing material, used to process a raw material into the ferromagnetic sensing material. The manufacturing system of the ferromagnetic sensing material includes a rotating device, a working cavity, a carrying element, an array magnet module, a spin wave excitation device, a baffle module, a measuring device, and a control unit. The rotating device includes a body and a rotating shaft extending from the body. The working cavity is sleeved on the rotating shaft. The carrying element is sleeved on the rotating shaft and disposed in an internal space of the working cavity to carry the raw material. The array magnet module is sleeved on the rotating shaft to provide a fixed magnetic field to the working cavity through rotation. The spin wave excitation device is configured to provide a high-frequency magnetic field spin wave to the raw material. The baffle module includes a shielding member to change an electromagnetic wave distribution in the working cavity through movement. The measuring device is configured to provide a sensing beam to the ferromagnetic sensing material and to receive a reflected beam from the ferromagnetic sensing material. The control unit is electrically connected to the rotating device, the spin wave excitation device, and the measuring device. The control unit obtains a magnetization result of the ferromagnetic sensing material according to the reflected beam, and the rotating device drives the carrying element and the array magnet module to rotate.

The disclosure further provides a manufacturing method of a ferromagnetic sensing material, including the following. A raw material is provided to a carrying element in a working cavity. A high-frequency magnetic field spin wave is provided to the raw material of a driving element. The driving element and the carrying element are rotated to provide a fixed magnetic field to an internal space of the driving element working cavity, and a driving element rotating platform is rotated, so as to process the raw material into the ferromagnetic sensing material. A sensing beam is provided to the ferromagnetic sensing material of the driving element to generate a reflected beam. A magnetization result of the ferromagnetic sensing material of the driving element is obtained according to the reflected beam of the driving element.

Based on the above, in the manufacturing system and the manufacturing method of the ferromagnetic sensing material in the disclosure, the raw material is processed into the ferromagnetic sensing material. The manufacturing system of the ferromagnetic sensing material includes the rotating device, the working cavity, the carrying element, the array magnet module, the spin wave excitation device, the measuring device, and the control unit. The rotating device includes the rotating shaft. The carrying element is disposed in the internal space of the working cavity to carry the raw material. The array magnet module is used to provide the fixed magnetic field. The spin wave excitation device is used to provide the high-frequency magnetic field spin wave. The baffle module is used to change the electromagnetic wave distribution in the working cavity. The measuring device is used to measure the ferromagnetic sensing material. The rotating device drives the carrying element and the array magnet module to rotate. In this way, the ferromagnetic sensing material with high sensing sensitivity, high tunneling magnetoresistance, and high thermal stability may be manufactured.

In order for the aforementioned features and advantages of the disclosure to be more comprehensible, embodiments accompanied with drawings are described in detail below.

### BRIEF DESCRIPTION OF THE DRAWINGS

FIG. 1 is a schematic view of a manufacturing system of a ferromagnetic sensing material according to an embodiment of the disclosure.

FIGS. 2A and 2B are respectively schematic top views of a ferromagnetic sensing material according to different embodiments of the disclosure.

FIGS. 3A and 3B are respectively schematic top views of a carrying element according to different embodiments of the disclosure.

FIG. 3C is a schematic side view of the carrying element in FIG. 3B.

FIG. 4 is a schematic top view of the manufacturing system of a portion of the ferromagnetic sensing material in FIG. 1.

FIGS. 5A to 5E are respectively views of electromagnetic wave distributions of a shielding member at different positions in the manufacturing system of the ferromagnetic sensing material in FIG. 1.

FIGS. 6A and 6B are respectively hysteresis graphs in different directions before processing by the manufacturing system of the ferromagnetic sensing material in FIG. 1.

FIGS. 7A and 7B are respectively hysteresis graphs in different directions after processing by the manufacturing system of the ferromagnetic sensing material in FIG. 1.

FIG. 8 is a flowchart of steps of a manufacturing method of a ferromagnetic sensing material according to an embodiment of the disclosure.

### DETAILED DESCRIPTION OF DISCLOSED EMBODIMENTS

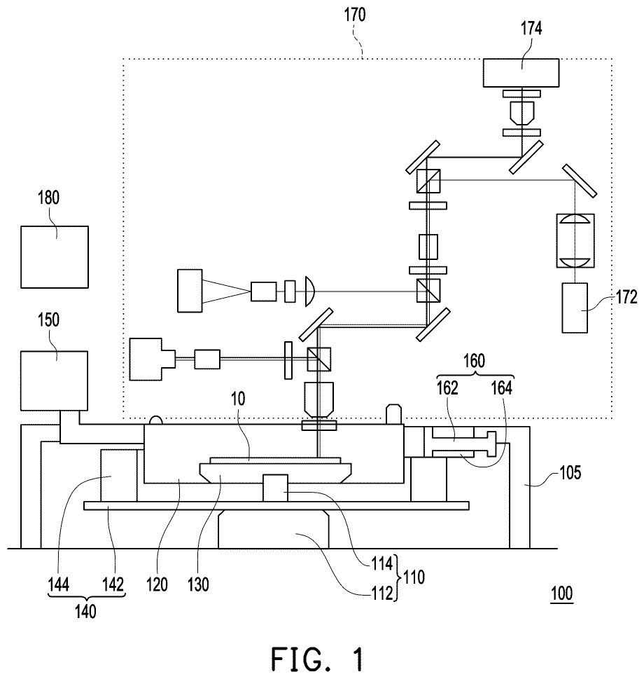

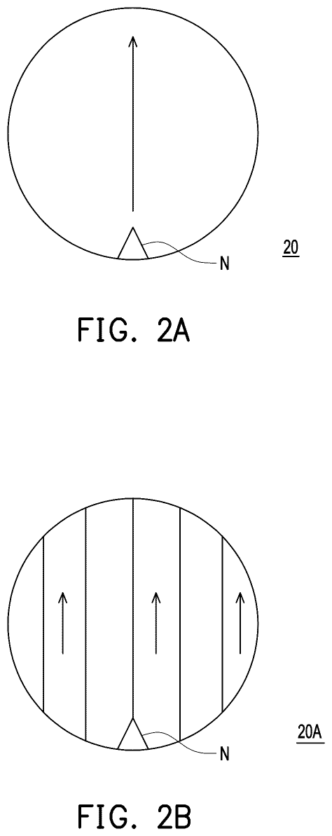

FIG. 1 is a schematic view of a manufacturing system of a ferromagnetic sensing material according to an embodiment of the disclosure. Referring to FIG. 1, in this embodiment, a manufacturing system 100 of the ferromagnetic sensing material is provided to perform magnetic moment processing on a raw material 10, so that the raw material 10 is formed into a ferromagnetic sensing material 20 (see FIG. 2A) with a magnetic easy axis distributed in a single direction. The raw material 10 is a wafer. For example, a 12-inch wafer is used, but the disclosure is not limited thereof, and wafers of different sizes may also be replaced according to requirements. A magnetic anisotropy field of the ferromagnetic sensing material 20 is between 1 and 550 milliteslas, and a temperature resistance range thereof may be between −40 and 200 degrees Celsius. The ferromagnetic sensing material 20 in this embodiment has characteristics of high sensing sensitivity, high tunneling magnetoresistance, and high thermal stability, so it may be applied to applications such as in-plane anisotropy control of a MTJ (magnetic tunnel junction) magnetic sensor, perpendicular anisotropy control of the MTJ magnetic sensor, magnetic anisotropy spatial distribution control of the MTJ magnetic sensor, SOT/STT-MRAM perpendicular anisotropy enhancement, exchange bias control of the MTJ magnetic sensor/MRAM antiferromagnetic layer, improvement of perpendicular anisotropic MTJ tunneling magnetoresistance, improvement of in-plane anisotropic MTJ thermal stability, or improvement of perpendicular anisotropic MTJ thermal stability.

FIGS. 2A and 2B are respectively schematic top views of a ferromagnetic sensing material according to different embodiments of the disclosure. Referring to FIGS. 1 to 2B, in addition, in this embodiment, different types of wafer stages may be used to manufacture the ferromagnetic sensing material 20 with distribution of different magnetic easy axes. For example, the manufacturing system 100 of the ferromagnetic sensing material in this embodiment may manufacture the ferromagnetic sensing material 20 in which the magnetic easy axis of the entire wafer is along a direction of a notch N. That is, the ferromagnetic sensing material 20 has one single magnetic easy axis, as shown in FIG. 2A. In addition, a ferromagnetic sensing material 20A with the magnetic easy axes distributed in a periodic spatial arrangement may be manufactured, and a period thereof is, for example, 10 mm, as shown in FIG. 2B.

In this embodiment, the manufacturing system 100 of the ferromagnetic sensing material includes a rotating device 110, a working cavity 120, a carrying element 130, an array magnet module 140, a spin wave excitation device 150, a baffle module 160, and a measuring device 170, and a control unit 180.

The rotating device 110 includes a body 112 and a rotating shaft 114 extending from the body 112. The rotating device 110 is, for example, a variable speed rotating stage, and is adapted to drive the rotating shaft 114 to rotate. In this embodiment, the rotating device 110 only drives the carrying element 130 and the array magnet module 140 to rotate, but the disclosure is not limited thereto. More specifically, in this embodiment, when the rotating device 110 rotates the carrying element 130 and the array magnet module 140, the carrying element 130 and the array magnet module 140 rotate concentrically.

The working cavity 120 is sleeved on the rotating shaft 114, and the working cavity 120 has an internal space to accommodate the raw material 10. In other words, the internal space of the working cavity 120 is a processing environment. In this embodiment, the working cavity 120 is, for example, a stainless steel polygonal cavity with an impedance of approximately 50 ohms. A working pressure thereof is substantially equal to 1 atmosphere, and a working temperature thereof is less than or equal to 100 degrees Celsius, for example, below 90 degrees Celsius. Therefore, in this embodiment, there is a more controllable working environment, which may further reduce the processing time. In addition, the working cavity 120 is configured as a polygonal cavity, such as a pentagon to an octagon, which helps to improve distribution uniformity of spin wave energy in the working cavity 120. In this embodiment, a hexagonal cavity is taken as an example for description. When the rotating device 110 rotates the carrying element 130 and the array magnet module 140, the working cavity 120 remains stationary. For example, in this embodiment, the manufacturing system 100 of the ferromagnetic sensing material further includes a base 105 connected to the working cavity 120 to fix the working cavity 120.

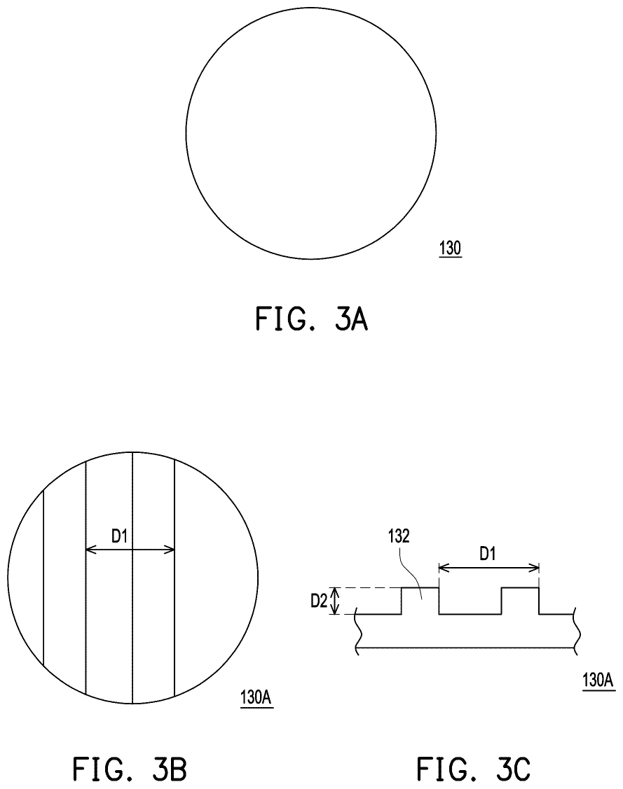

FIGS. 3A and 3B are respectively schematic top views of a carrying element according to different embodiments of the disclosure. FIG. 3C is a schematic side view of the carrying element in FIG. 3B. Referring to FIG. 1 and FIGS. 3A to 3C, the carrying element 130 is sleeved on the rotating shaft 114 of the rotating device 110 so as to be rotated according to the driving of the rotating device 110. The carrying element 130 is disposed in the internal space of the working cavity 120 to carry the raw material 10. In this embodiment, to manufacture the ferromagnetic sensing material 20 with the single magnetic easy axis (as shown in FIG. 2A), the carrying element 130 must be, for example, configured as a flat 12-inch silicon carbide wafer stage with a surface height difference of less than 5 mm as shown in FIG. 3A. In another embodiment, to manufacture the ferromagnetic sensing material 20A with the magnetic easy axes distributed in the periodic spatial arrangement in the period of 10 mm (as shown in FIG. 2B), a carrying element 130A must be, for example, configured as the 12-inch silicon carbide wafer stage having a surface with a height difference, as shown in FIGS. 3B and 3C. That is, different configurations or sizes of stages may be used according to requirements. Specifically, a surface of the carrying element 130A has multiple platform structures 132 arranged periodically, a height D2 of the platform structure 132 is 5 mm, and an arrangement period D1 of the platform structures 132 is 10 mm. The disclosure is not limited thereto.

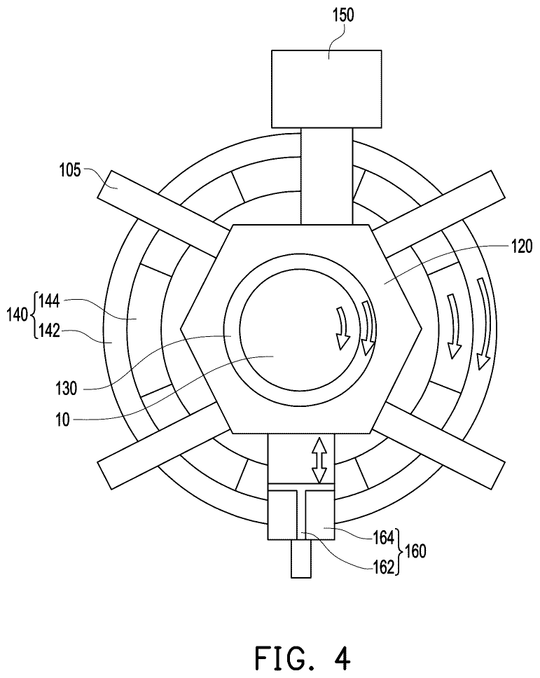

FIG. 4 is a schematic top view of the manufacturing system of a portion of the ferromagnetic sensing material in FIG. 1. Referring to FIGS. 1 and 4, the array magnet module 140 is sleeved on the rotating shaft 114 of the rotating device 110 to provide a fixed magnetic field to the working cavity 120 through rotation. The array magnet module 140 is, for example, a Halbach array magnet. Specifically, in this embodiment, the array magnet module 140 includes a rotating platform 142 and multiple magnets 144. The rotating platform 142 is sleeved on the rotating shaft 114 of the rotating device 110. The magnets 144 are disposed on the rotating platform 142, arranged in a ring shape and surrounding the working cavity 120. The rotating device 110 rotates the rotating platform 142 of the array magnet module 140 to drive the magnets 144 to generate the fixed magnetic field. Since the carrying element 130 and the array magnet module 140 rotate concentrically, a direction of the fixed magnetic field generated by the array magnet module 140 is always consistent with a direction of the easy axis with the magnetic anisotropy on the raw material 10.

The spin wave excitation device 150 is configured to provide a high-frequency magnetic field spin wave to the raw material 10. For example, in this embodiment, a frequency of the high-frequency magnetic field spin wave ranges from 1 to 5 GHz, and power of the high-frequency magnetic field spin wave ranges from 1 to 6 KW. In different manufacturing processes, the power of the high-frequency magnetic field spin wave may be designed according to different rotation speeds of the rotating device 110. In a preferred embodiment, the rotation speed of the rotating device 110 is 5/min, and the power of the high-frequency magnetic field spin wave is set to 1.5 KW, which may enable the anisotropy field to reach 550 milliteslas. However, the disclosure is not limited thereto.

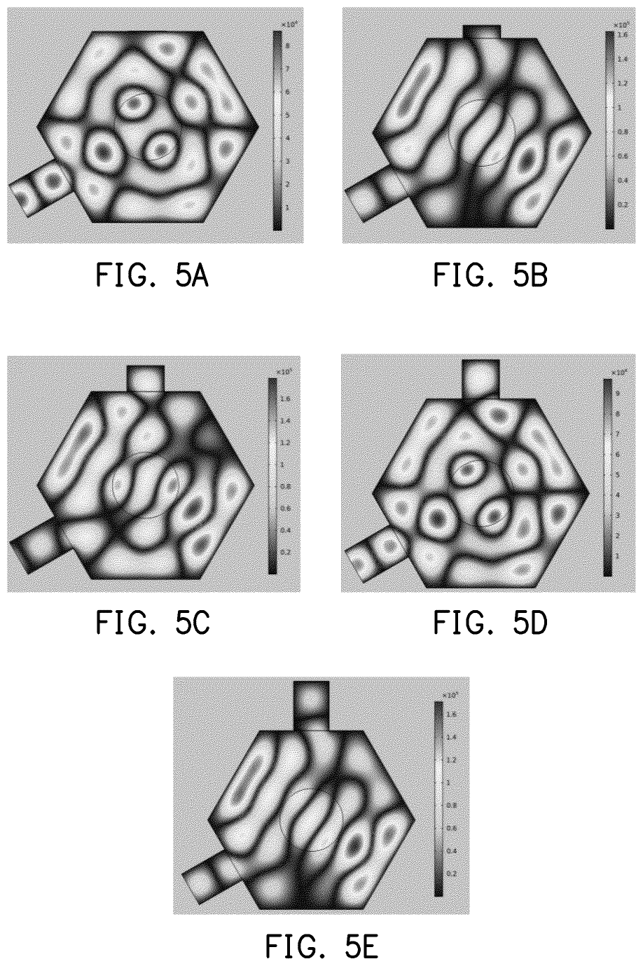

FIGS. 5A to 5E are respectively views of electromagnetic wave distributions of a shielding member at different positions in the manufacturing system of the ferromagnetic sensing material in FIG. 1. Referring to FIG. 1 and FIGS. 4 to 5E, the baffle module 160 includes a shielding member 162 with a movement range between 0 and 100 centimeters, which is used to change the electromagnetic wave distributions in the working cavity 120 through movement (such as reciprocating linear movement). As shown in FIGS. 5A to 5E respectively, distances from the shielding member 162 to the working cavity 120 are 0 cm, 5 cm, 10 cm, 15 cm, and 20 cm respectively. It may be seen that when the distance between the shielding member 162 and the working cavity 120 is 0 cm and 15 cm, the electromagnetic wave distributions in the working cavity 120 are similar. Therefore, it may be concluded that a change period of the electromagnetic wave distribution thereof is 15 cm. Specifically, in this embodiment, the baffle module 160 further includes a driving element 164 connected to the shielding member 162 to drive the shielding member 162 to move to change a position of the shielding member 162. In this embodiment, when the driving element 164 drives the shielding member 162, the shielding member 162 moves in simple harmonic motion, and a motion period thereof is between 5 and 30 seconds.

The measuring device 170 is configured to provide a sensing beam to the ferromagnetic sensing material 20 and to receive a reflected beam from the ferromagnetic sensing material 20. The measuring device 170 is, for example, a dual-beam measuring system, including a first light source 172 and a second light source 174. The first light source 172 is used to provide a first light beam, and the second light source 174 is used to provide a second light beam. A light path of the first light beam is different from a light path of the second light beam. Specifically, the measuring device 170 is a dual light path magneto-optical measuring system that may measure the ferromagnetic sensing material 20 located in the working cavity 120 in real time. The dual light path magneto-optical measuring system includes, for example, elements such as laser light sources, white light sources, polarizing prisms, balanced photodetectors, charge-coupled device cameras to monitor an effect of magnetic annealing polarization in real time.

The control unit 180 includes, for example, a central processing unit (CPU), other programmable general-purpose or special-purpose microprocessors, a digital signal processor (DSP), a programmable controller, an application specific integrated circuit (ASIC), or other similar elements or a combination of the above elements, electrically connected to the rotating device 110, the spin wave excitation device 150, and the measuring device 170 to serve as a data reception and process condition controller of the manufacturing system 100 of the ferromagnetic sensing material. The control unit 180 obtains a magnetization result of the ferromagnetic sensing material 20 according to the reflected beam of the ferromagnetic sensing material 20.

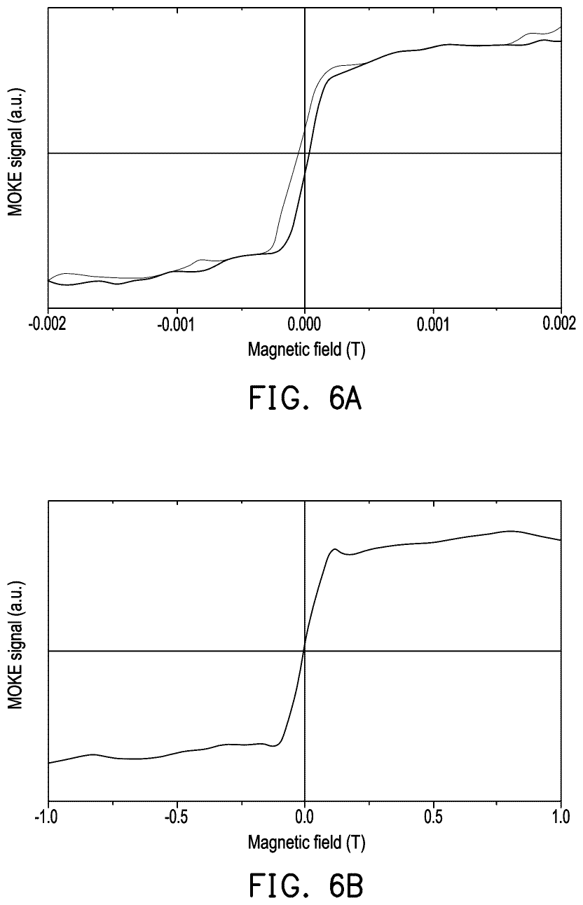

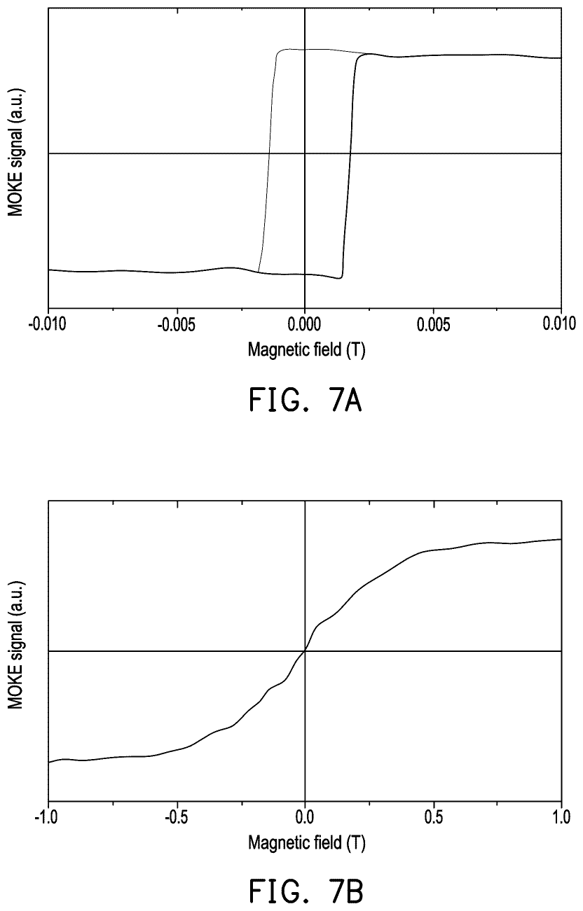

FIGS. 6A and 6B are respectively hysteresis graphs in different directions before processing by the manufacturing system of the ferromagnetic sensing material in FIG. 1. FIGS. 7A and 7B are respectively hysteresis graphs in different directions after processing by the manufacturing system of the ferromagnetic sensing material in FIG. 1. Referring to FIGS. 6A to 7B, after the ferromagnetic sensing material 20 is processed by the manufacturing system 100 of the ferromagnetic sensing material in FIG. 1 of this embodiment, before an effect of spin wave annealing, similar hysteresis curves may be obtained in a vertical plane direction and a parallel plane direction respectively, as shown in FIGS. 6A and 6B. After the effect of spin wave annealing, corresponding hysteresis curves may be obtained in the vertical plane direction and the parallel plane direction respectively, as shown in FIGS. 7A and 7B. As shown in FIGS. 7A and 7B, the ferromagnetic sensing material 20 in this embodiment has better thermal stability and tunneling magnetoresistance, and therefore has high sensing sensitivity.

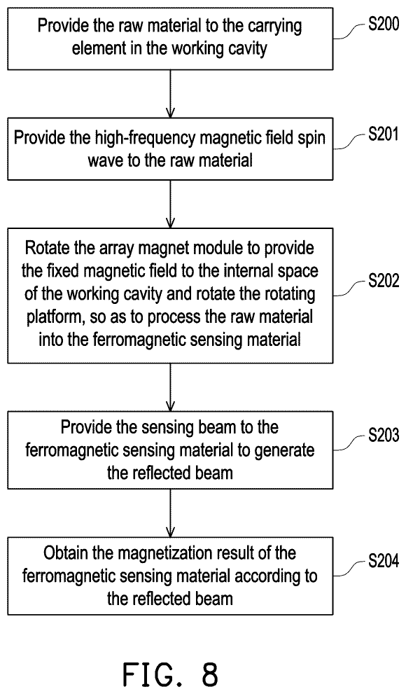

FIG. 8 is a flowchart of steps of a manufacturing method of a ferromagnetic sensing material according to an embodiment of the disclosure. Referring to FIGS. 1, 2A, 4, and 8, the manufacturing method of the ferromagnetic sensing material in this embodiment may be applied to at least the manufacturing system 100 of the ferromagnetic sensing material shown in FIGS. 1 and 4, so it is taken as an example for description in the following. In this embodiment, a manufacturing method of the ferromagnetic sensing material 20 is provided. First, step S200 is performed to provide the raw material 10 to the carrying element 130 in the working cavity 120. Next, after the above step, step S201 is performed to provide the high-frequency magnetic field spin wave to the raw material 10. Specifically, the spin wave excitation device 150 of the manufacturing system 100 of the ferromagnetic sensing material provides the high-frequency magnetic field spin wave to the raw material 10 in the working cavity 120. Next, after the above step, step S202 is performed to rotate the array magnet module 140 to provide the fixed magnetic field to the internal space of the working cavity 120 and rotate the rotating platform 130, so as to process the raw material 10 into the ferromagnetic sensing material 20. Specifically, the rotating device 110 of the manufacturing system 100 of the ferromagnetic sensing material rotates the carrying element 130 and the array magnet module 140 synchronously. The array magnet module 140 provides the fixed magnetic field to the working cavity 120 through rotation, and the direction of the fixed magnetic field generated by the array magnet module 140 is always consistent with the direction of the easy axis with the magnetic anisotropy on the raw material 10. Through an effect of the high-frequency magnetic field spin wave, the ferromagnetic sensing material 20 is formed. Next, after the above step, step S203 is performed to provide the sensing beam to the ferromagnetic sensing material 20 to generate the reflected beam. Specifically, the measuring device 170 provides the sensing beam to the ferromagnetic sensing material 20 and receives the reflected beam from the ferromagnetic sensing material 20 to monitor the effect of magnetic annealing polarization in real time. Finally, after the above step, step S204 is performed to obtain the magnetization result of the ferromagnetic sensing material 20 according to the reflected beam. As a result, the ferromagnetic sensing material 20 generated by the manufacturing method of the ferromagnetic sensing material 20 in this embodiment has the characteristics of high sensing sensitivity, high tunneling magnetoresistance, and high thermal stability.

Based on the above, in the manufacturing system and the manufacturing method of the ferromagnetic sensing material in the disclosure, the raw material is processed into the ferromagnetic sensing material. The manufacturing system of the ferromagnetic sensing material includes the rotating device, the working cavity, the carrying element, the array magnet module, the spin wave excitation device, the baffle module, the measuring device, and the control unit. The rotating device includes the rotating shaft. The carrying element is disposed in the internal space of the working cavity to carry the raw material. The array magnet module is used to provide the fixed magnetic field. The spin wave excitation device is used to provide the high-frequency magnetic field spin wave. The baffle module is used to change the electromagnetic wave distribution in the working cavity. The measuring device is used to measure the ferromagnetic sensing material. The rotating device drives the carrying element and the array magnet module to rotate. In this way, the ferromagnetic sensing material with high sensing sensitivity, high tunneling magnetoresistance, and high thermal stability may be manufactured.

Although the disclosure has been described with reference to the above embodiments, they are not intended to limit the disclosure. It will be apparent to one of ordinary skill in the art that modifications to the described embodiments may be made without departing from the spirit and the scope of the disclosure. Accordingly, the scope of the disclosure will be defined by the attached claims and their equivalents and not by the above detailed descriptions.

What is claimed is:

1. A manufacturing system of a ferromagnetic sensing material, used to process a raw material into the ferromagnetic sensing material, comprising:
a rotating device comprising a body and a rotating shaft extending from the body;
a working cavity sleeved on the rotating shaft;
a carrying element sleeved on the rotating shaft and disposed in an internal space of the working cavity to carry the raw material;
an array magnet module sleeved on the rotating shaft to provide a fixed magnetic field to the working cavity through rotation;
a spin wave excitation device configured to provide a high-frequency magnetic field spin wave to the raw material;
a baffle module comprising a shielding member to change an electromagnetic wave distribution in the working cavity through movement;
a measuring device configured to provide a sensing beam to the ferromagnetic sensing material and to receive a reflected beam from the ferromagnetic sensing material; and
a control unit electrically connected to the rotating device, the spin wave excitation device, and the measuring device, wherein the control unit obtains a magnetization result of the ferromagnetic sensing material according to the reflected beam, and the rotating device drives the carrying element and the array magnet module to rotate.

2. The manufacturing system of the ferromagnetic sensing material according to claim 1, wherein when the rotating device rotates the carrying element and the array magnet module, the carrying element and the array magnet module rotate concentrically.

3. The manufacturing system of the ferromagnetic sensing material according to claim 1, wherein a magnetic anisotropy field of the ferromagnetic sensing material is between 1 and 550 milliteslas.

4. The manufacturing system of the ferromagnetic sensing material according to claim 1, wherein a temperature resistance range of the ferromagnetic sensing material is between −40 and 200 degrees Celsius.

5. The manufacturing system of the ferromagnetic sensing material according to claim 1, wherein the ferromagnetic sensing material has a single magnetic easy axis.

6. The manufacturing system of the ferromagnetic sensing material according to claim 1, wherein the ferromagnetic sensing material has magnetic easy axes arranged periodically.

7. The manufacturing system of the ferromagnetic sensing material according to claim 1, wherein a working pressure of the working cavity is approximately equal to 1 atmosphere, and a working temperature of the working cavity is less than or equal to 100 degrees.

8. The manufacturing system of the ferromagnetic sensing material according to claim 1, wherein the working cavity is a polygonal cavity.

9. The manufacturing system of the ferromagnetic sensing material according to claim 1, wherein when the rotating device rotates the carrying element and the array magnet module, the working cavity remains stationary.

10. The manufacturing system of the ferromagnetic sensing material according to claim 1, further comprising:
a base connected to the working cavity to fix the working cavity.

11. The manufacturing system of the ferromagnetic sensing material according to claim 1, wherein a surface height difference of the carrying element is less than 5 mm.

12. The manufacturing system of the ferromagnetic sensing material according to claim 1, wherein a surface of the carrying element has a plurality of platform structures arranged periodically, and a height of each of the platform structure is greater than or equal to 5 mm.

13. The manufacturing system of the ferromagnetic sensing material according to claim 1, wherein the array magnet module comprises a rotating platform and a plurality of magnets, the rotating platform is sleeved on the rotating shaft of the rotating device, the magnets are disposed on the rotating platform, arranged in a ring shape and surrounding the working cavity, and the rotating device rotates the rotating platform to drive the magnets, thereby generating the fixed magnetic field.

14. The manufacturing system of the ferromagnetic sensing material according to claim 1, wherein a frequency of the high-frequency magnetic field spin wave is between 1 and 5 GHz, and power of the high-frequency magnetic field spin wave is between 1 and 6 KW.

15. The manufacturing system of the ferromagnetic sensing material according to claim 1, wherein a movement range of the shielding member is between 0 and 100 centimeters.

16. The manufacturing system of the ferromagnetic sensing material according to claim 1, wherein the baffle module further comprises a driving element connected to the shielding member to move the shielding member to change a position of the shielding member.

17. The manufacturing system of the ferromagnetic sensing material according to claim 16, wherein when the driving element drives the shielding member, the shielding member moves in simple harmonic motion, and a motion period thereof is between 5 and 30 seconds.

18. The manufacturing system of the ferromagnetic sensing material according to claim 1, wherein the measuring device comprises a first light source and a second light source, the first light source is used to provide a first light beam, the second light source is used to provide a second light beam, and a light path of the first light beam is different from a light path of the second light beam.

19. A manufacturing method of a ferromagnetic sensing material, comprising:
providing a raw material to a carrying element in a working cavity;
providing a high-frequency magnetic field spin wave to the raw material;
rotating the carrying element to provide a fixed magnetic field to an internal space of the working cavity, and rotating a rotating platform, so as to process the raw material into the ferromagnetic sensing material;
providing a sensing beam to the ferromagnetic sensing material to generate a reflected beam; and
obtaining a magnetization result of the ferromagnetic sensing material according to the reflected beam.

20. The manufacturing method of the ferromagnetic sensing material according to claim 19, further comprising:
moving a shielding member of a baffle module to change an electromagnetic wave distribution in the working cavity.
